(19) United States
(12) Patent Application Publication
(10) Pub. No.: US 2026/0033387 A1
(43) Pub. Date: Jan. 29, 2026

(54) 3D INTEGRATED CIRCUIT DEVICE AND RELATED METHODS

(71) Applicant: Taiwan Semiconductor Manufacturing Company, Ltd., Hsinchu (TW)

(72) Inventors: Stefan Rusu, Sunnyvale, CA (US); Tai-Chun Huang, New Taipei City (TW); Lan-Chou Cho, Hsinchu City (TW)

(21) Appl. No.: 18/923,406

(22) Filed: Oct. 22, 2024

Related U.S. Application Data
(60) Provisional application No. 63/674,695, filed on Jul. 23, 2024.

(51) Int. Cl. H01L 25/16; G02B 6/12; H01L 23/00; H01L 23/367; H01L 23/538; H10B 80/00

(52) U.S. Cl. CPC H01L 25/167; G02B 6/12002; H01L 23/3675; H01L 23/5385; H01L 24/14; H01L 24/16; H01L 24/17; H01L 24/32; H01L 24/73; H01L 2224/1403; H01L 2224/16145; H01L 2224/16225; H01L 2224/17181; H01L 2224/32221; H01L 2224/73253; H10B 80/00; H10D 1/68

(57) ABSTRACT

A package substrate according to the present disclosure includes a package substrate, an interposer disposed over the package substrate, a photonic die disposed over the interposer, a memory structure disposed over the interposer and including a controller die, a system die disposed over the interposer and partially overlapping with the photonic die and the controller die, and a lid covering the system die, the memory structure, and photonic die. The system die includes micro bumps extending from a bottom surface of the system die to a top surface of the controller die.

### PRIORITY DATA

This application claims the benefit of U.S. Provisional Application No. 63/674,695, filed Jul. 23, 2024, which is hereby incorporated by reference in its entirety.

### BACKGROUND

Three-dimensional integrated circuit (3D IC) technology improves the performance and efficiency of chips by bringing peripheral chips closer to a center system-on-chip (SoC) and achieving edge-to-edge 3D connections, while also improving system stability and reliability. 3D IC technology also provides for chip density to be increased, area utilization efficiency to be improved, and provides for higher performance and efficiency. Further, integrating different types of chips (e.g., such as CPUs, GPUs, and memory) can provide for more efficient data processing and storage, thereby improving the overall performance and efficiency of the system. Optical integration, on the other hand, can achieve more efficient data transmission and communication by integrating optical chips with electronic chips, utilizing the high speed and low latency characteristics of optical transmission to increase communication speed and efficiency, reduce transmission loss and thermal effects, and achieve higher bandwidth and lower power consumption.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a top see-through view of a package structure, according to various aspects of the present disclosure.

FIG. 2 is a sectional view of the package structure in FIG. 1, according to various aspects of the present disclosure.

FIG. 3 is a sectional view of the package structure in FIG. 1, according to various aspects of the present disclosure.

FIG. 4 is an enlarged fragmentary cross-sectional view of an overlapping area between a system die and a photonic die, according to various aspects of the present disclosure.

FIG. 5 is an enlarged fragmentary cross-sectional view of an overlapping area between a system die and a photonic die, according to various aspects of the present disclosure.

FIG. 6 is an enlarged fragmentary cross-sectional view of an overlapping area between a system die and a memory structure, according to various aspects of the present disclosure.

FIG. 7 illustrates a flowchart of a method for forming a package structure, according to various aspects of the present disclosure.

FIGS. 8-18 illustrate cross-sectional views or top views of a precursor structure going through various steps of the method in FIG. 7, according to various aspects of the present disclosure.

FIGS. 19-28 illustrate alternative embodiments according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor packaging technologies were once considered backend processes that facilitate chips to interface external circuitry. It is no longer the case. Computing workloads have evolved so much that brought packaging technologies to the forefront of innovation. Modern packaging provides integration of multiple chips or dies into a single semiconductor device. Integration of chips generally comes in two flavors—a two-dimensional (2D) architecture and a three-dimensional (3D) architecture. In a 2D architecture, dies are packaged separately and mounted on a circuit board and the conductive traces in the circuit board interconnect the separately packaged dies. An integrated circuit (IC) with a 3D architecture includes more than one dies that are stacked vertically. Such 3D IC technology improves the performance and efficiency of chips by bringing peripheral chips closer to a center system-on-chip (SoC) and achieving edge-to-edge 3D connections, while also improving system stability and reliability. 3D IC technology also leads to increased chip density, improved area utilization efficiency, higher performance, and greater efficiency. Further, integrating different types of chips (e.g., such as central processing units (CPUs), graphics processing units (GPUs), and memory) can provide for more efficient data processing and storage, thereby improving the overall performance and efficiency of the system. Optical chips may be integrated with electronic chips to take advantage of the high speed and low latency characteristics of optical transmission to increase communication speed and efficiency, reduce transmission loss and thermal effects, and achieve higher bandwidth and lower power consumption.

The present disclosure provides package structures that minimizes distances between peripheral dies and a central system die, reduces optical interference, and increases heat dissipation efficiency. In some examples, an interposer is bonded to a package substrate. A photonic die and a memory structure are bonded to the interposer. A system die is disposed over the photonic die, the memory structure, and interposer such that the system die partially and vertically overlaps with portions of the photonic die and the memory structure. The package structure also includes electronic dies bonded to a top surface of the photonic die. In some instances, the electric dies may be integrated into the system die. An alternative package structure includes an interposer bonded to a package structure and a system die bonded to the interposer. A photonic die is bonded to and overhanging the system die. A memory structure includes a controller die and a memory stack. In the alternative package structure, the controller dies is bonded to the top surface of the system die. The package structures of the present disclosure include a heat spreader attached to the package substrate. The heat spreader help dissipate heat from the system die, the electronic die, the controller die, and the photonic die. In some instances, the photonic die includes an optical coupler to couple to a fiber array.

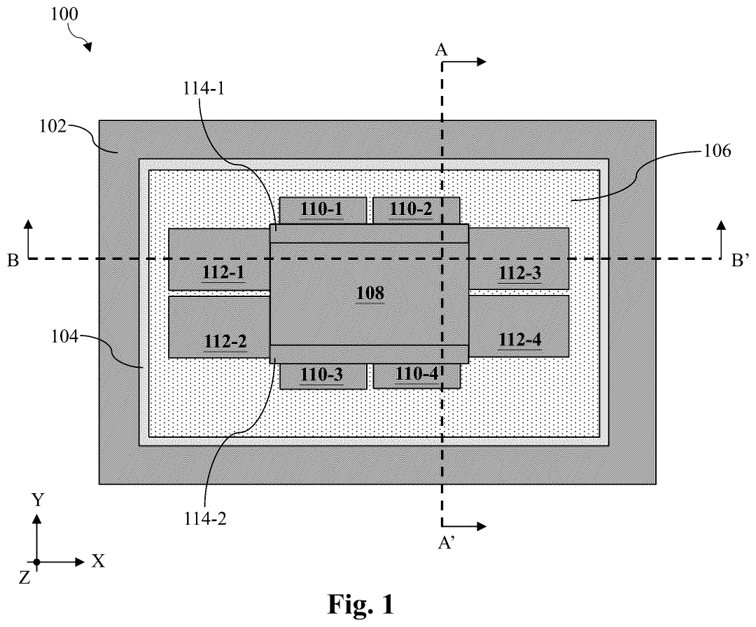

Reference is first made to FIG. 1, which illustrate a top see-through view of a package structure 100. The package structure 100 includes a package substrate 102, an interposer 106 bonded to the package substrate 102. In the depicted embodiments, the package structure 100 includes four photonic dies and four memory structures bonded to a top surface of the interposer 106. Other arrangements, which may include more or less of the photonic dies or memory structures, are possible. As shown in FIG. 1, the four photonic dies include a first photonic die 110-1, a second photonic die 110-2, a third photonic die 110-3, and a fourth photonic die 110-4. The four memory structures include a first memory structure 112-1, a second memory structure 112-2, a third memory structure 112-3, and a fourth memory structure 112-4. The package structure 100 further includes a first electronic die 114-1 that partially overlaps the first photonic die 110-1 and the second photonic die 110-2 and a second electronic die 114-2 that partially overlaps the third photonic die 110-3 and the fourth photonic die 110-4. The package structure 100 also includes a system die 108 that partially overlaps with the memory structures and the photonic dies. The system die 108, the first photonic die 110-1, the second photonic die 110-2, the third photonic die 110-3, the fourth photonic die 110-4, the first memory structure 112-1, the second memory structure 112-2, the third memory structure 112-3, and the fourth memory structure 112-4 are covered by a heat spreader 104 that is attached to a top surface of the package substrate 102. The top see-through view of the package structure 100 in FIG. 1 shows a cross-section of a sidewall of the heat spreader 104, which will be described further below.

In some embodiments, the package substrate 102 may include a printed circuit board (PCB) or the like, which may include fiberglass reinforced epoxy resin (FR-4), Polytetrafluoroethylene (PTFE), and metal traces. The system die 108 may include a graphic processing unit (GPU), a central processing unit (CPU), a neural processing unit (NPU), or a combination thereof to perform various applications. In some instances, the system die 108 may also be referred to as a System-on-Chip (SoC) die 108. Each of the photonic dies 110-1, 110-2, 110-3, and 110-4 refers to a die that includes two or more photonic components and detects, generates, transports, and process light signals. A photonic die may also be referred to as a P-die or a photonic integrated circuit (PIC). Each of the electronic dies 114-1 and 114-2 may be referred to as an E-die or an electronic integrated circuit (EIC). In some embodiments, the photonic dies may convert optical signals into electrical signals and send the electrical signal to the electronic dies. The photonic dies may also convert electrical signals received from the electronic dies into optical signal and send the optical signal via a fiber array. The electronic dies interface the photonic dies.

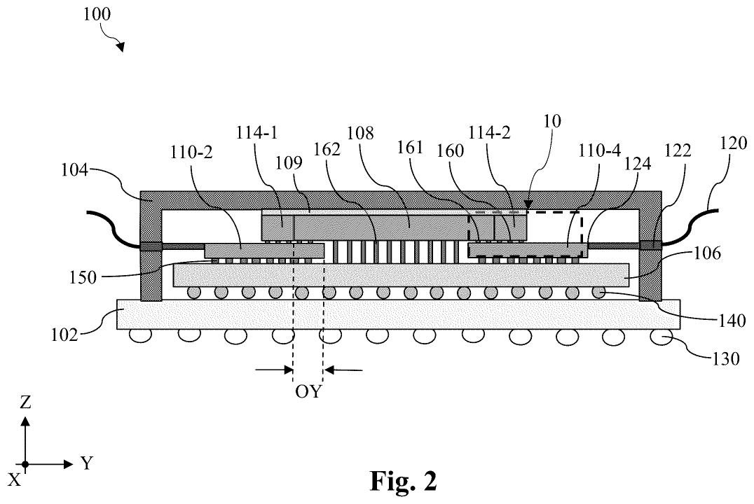

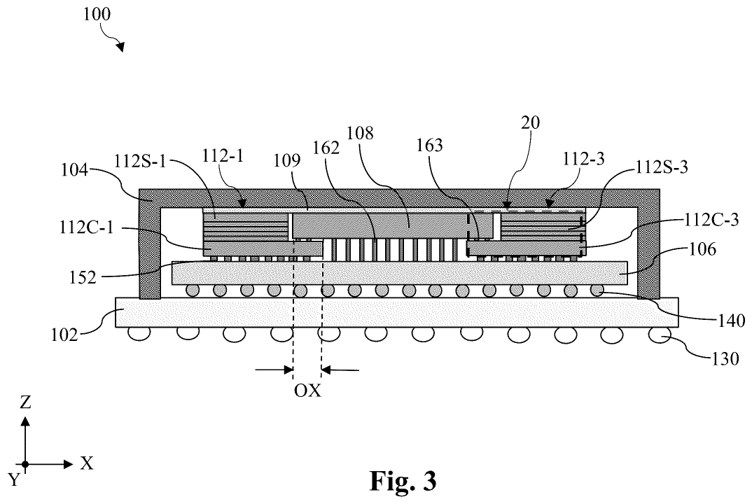

FIG. 1 includes a cross-section A-A′ that cuts through the second photonic die 110-2, the first electronic die 114-1, the system die 108, the second electronic die 114-2, and the fourth photonic die 110-4 along the Y direction. A cross-sectional view along cross-section A-A′ is shown in FIG. 2. Additionally, FIG. 1 includes a cross-section B-B′ that cuts through the first memory structure 112-1, the system die 108, and the third memory structure 112-3 along the X direction. A cross-sectional view along cross-section B-B′ is shown in FIG. 3.

Referring to FIG. 2, the package substrate 102 includes package bumps 130 such that the package structure 100 may be subsequently mounted on and coupled to a larger substrate. The interposer 106 is bonded to a top surface of the package substrate 102 by way of controlled collapse chip connection (C4) bumps 140. Each of the photonic dies, such as the second photonic die 110-2 and the fourth photonic die 110-4 shown in FIG. 2, are bonded to a top surface of the interposer 106 by way of micro bumps 150. The first electronic die 114-1 is bonded to top surfaces of the first photonic die 110-1 and the second photonic die 110-2 by way of micro bumps 160. Similarly, the second electronic die 114-2 is bonded to top surfaces of the third photonic die 110-3 and the fourth photonic die 110-4 by way of micro bumps 160. As shown in FIG. 2, the system die 108 partially overlaps with the photonic dies, such as the second photonic die 110-2 and the fourth photonic die 110-4. The overlap between the system die 108 and the photonic dies helps minimize electrical signal travel distances and maximize optical signal travel distances. Because optical signal travels faster than electrical signal and does so with minimal energy loss, the package structure 100 shown FIGS. 1, 2 and 3 may have improved performance and energy efficiency. It is noted that the system die 108 may be physically bonded to the top surface of the photonic dies, such as the second photonic die 110-2 and the fourth photonic die 110-4, by way of micro bumps 161. In some implementations, the system die 108 is not in direct communication with the photonic dies. In these implementations, the micro bumps 161 may either be dummy micro bumps that do not provide electrical connection between the system die 108 and the photonic dies or bond to a redistribution layer on top of the photonic dies to communicate with the electronic dies, such as the first electronic die 114-1 and the second electronic die 114-2. In some further implementations not explicitly illustrated in the figures, functions of electronic dies are integrated into the photonic dies such that the system die 108 may be directly connected to the photonic dies. In general, the C4 bumps (e.g., C4 bumps 140) and micro bumps (e.g., micro bumps 150, 160, or 161) have a circular profile when view along a vertical direction (i.e., the Z direction). A diameter of a C4 bump is substantially greater than a diameter of a micro bump. In some instances, a diameter of a micro bump may be between about 3 μm and about 30 μm and a diameter of a C4 bump may be between about 50 μm and about 200 μm.

In some embodiments represented in FIG. 2, the system die 108 may also be directly bonded to the top surface of the interposer 106 by way of a plurality of tall micro bumps 162. Because a bottom surface of the system die 108 is substantially flat, a height of each of the tall micro bumps 162 may be a sum of a height of micro bumps 150, a height of the micro bumps 160, and a thickness of the second photonic die 110-2 or the fourth photonic die 110-4. A height of the tall micro bumps 162 may be between about 5 μm and about 20 μm while of a height of the micro bumps 150 or the micro bumps 160 may be between about 0.5 μm and about 15 μm. In some instances, a ratio of the height of a tall micro bump to the height of a micro bump may be between about 4 and about 10. In FIG. 2, the second photonic die 110-2 and the fourth photonic die 110-4 are spaced apart along the Y direction. The first electronic die 114-1 and the second electronic die 114-2 are also spaced apart along the Y direction. The tall micro bumps 162 can be said to be disposed between the second photonic die 110-2 and the fourth photonic die 110-4 along the Y direction. The system die 108 can be said to be disposed between the first electronic die 114-1 and the second electronic die 114-2 along the Y direction. The vertical overlap between the system die 108 and the second photonic die 110-2 along the Y direction may be referred to as a Y-direction overlap (OY). In some instances, the OY may be between about 500 μm and about 1000 μm. In the embodiments shown in FIG. 2, the system die 108 also vertical overlaps the fourth photonic die 110-4 by the Y-direction overlap (OY).

Reference is still made to FIG. 2. The heat spreader 104 may come in a form of a metal lid. The heat spreader 104 engages a topmost surface of the package structure 100, such as top surfaces of the first electronic die 114-1, the second electronic die 114-2, and the system die 108, by way of a thermally conductive layer 109. In some embodiments, the thermally conductive layer 109 includes a thermal interface material (TIM). The heat spreader 104 may be attached to the top surface of the package substrate 102 by way of an adhesive. The TIM layer may include a gallium alloy, zinc oxide (ZnO), or aluminum nitride (AlN). The adhesive may include a die attach film (DAF), silicone, polyimide (PI), or epoxy. The heat spreader 104 may be formed of a metal or a metal alloy, such as aluminum (Al), copper (Cu), iron (Fe), stainless steel, nickel (Ni), cobalt (Co), or an alloy thereof. Example alloys may include an aluminum-copper alloy, an iron-nickel alloy, or an iron-nickel-cobalt alloy. As illustrated in FIG. 2, the photonic dies are coupled to fiber arrays to receive or emit optical signals. In some embodiments represented in FIG. 2, a fiber array 120 is coupled to a coupler 124 on each of the photonic dies via a fiber connector 122 that extends through a sidewall of the heat spreader 104. In some embodiments, the coupler 124 may be an edge coupler or a grating coupler. When the coupler 124 is an edge coupler, the coupler 124 is disposed along a sidewall of the photonic die, such as the second photonic die 110-2 or the fourth photonic die 110-4. When the coupler 124 is a grating coupler, the coupler 124 is disposed along a top surface of the photonic die, such as the second photonic die 110-2 or the fourth photonic die 110-4.

Reference is now made to FIG. 3. In some embodiments, each of the memory structures 112-1, 112-2, 112-3, and 112-4 may include a high-bandwidth-memory (HBM) construction. HBM is a computer memory interface that is commonly used in conjunction with high-performance graphics accelerators, high-performance data center, application specific integrated circuit (ASIC) for AI application, on-package cache in CPUs, or high-performance computing ICs. In the depicted embodiments, each of the memory structures may include a dynamic random access memory (DRAM) stack die (or memory stack die) and a controller die that is bonded to the DRAM stack die. In some instances, the DRAM stack die may include 2 to 10 DRAM dies stacked vertically. The vertical stacking allows for higher bandwidth, smaller power consumption, and smaller form factor. In FIG. 3, the first memory structure 112-1 includes a first memory stack 112S-1 bonded to a first controller die 112C-1. The third memory structure 112-3 includes a third memory stack 112S-3 bonded to a third controller die 112C-3. Although not explicitly shown in the drawings, it should be understood that the second memory structure 112-2 and the fourth memory structure 112-4 have a similar structure. Each of the second memory structure 112-2 and the fourth memory structure 112-4 includes a memory stack die bonded to a controller die.

Reference is still made to FIG. 3. The first controller die 112C-1 of the first memory structure 112-1 is bonded to the top surface of the interposer 106 by way of micro bumps 152. Similarly, the third controller die 112C-3 of the third memory structure 112-3 is bonded to the top surface of the interposer 106 by way of micro bumps 152. As shown in FIG. 3, the first memory structure 112-1 and the third memory structure 112-3 are spaced apart from one another along the X direction. More particularly, along the X direction, the system die 108 is disposed between the first memory stack 112S-1 and the third memory stack 112S-3. In order to reduce electrical signal travel distance, the system die 108 vertically overlaps with the first controller die 112C-1 and the third controller die 112C-3. The vertical overlap between the system die 108 and the controller dies along the X direction may be referred to as an X-direction overlap (OX). In some instances, the OX may be between about 500 μm and about 1000 μm. The system die 108 is directly bonded to the top surface of the interposer 106 by the tall micro bumps 162. Due to the X-direction overlap (OX), the system die 108 is also bonded to top surfaces of the controller dies (such as the first controller die 112C-1 and the third controller die 112C-3 in FIG. 3) by way of micro bumps 163. The micro bumps 163 may provide electrical connections between the system die 108 and the controller dies. As illustrated in FIG. 3, the heat spreader 104 covers the first memory structure 112-1, the second memory structure 112-2, the third memory structure 112-3, and the fourth memory structure 112-4. The thermally conductive layer 109 is sandwiched between a bottom surface of the heat spreader 104 and top surfaces of the memory structures to promote thermal conduction.

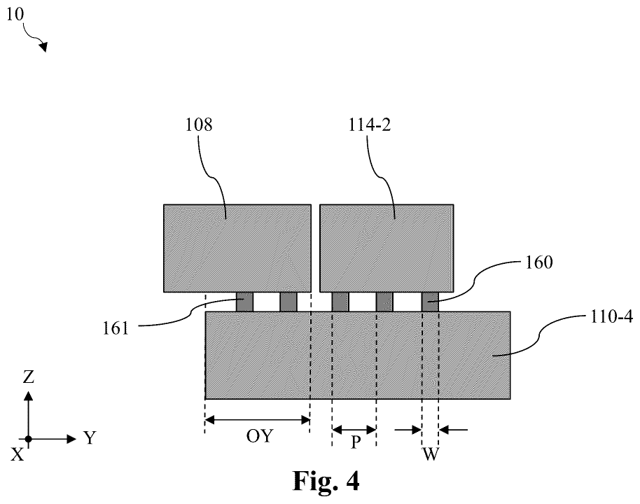

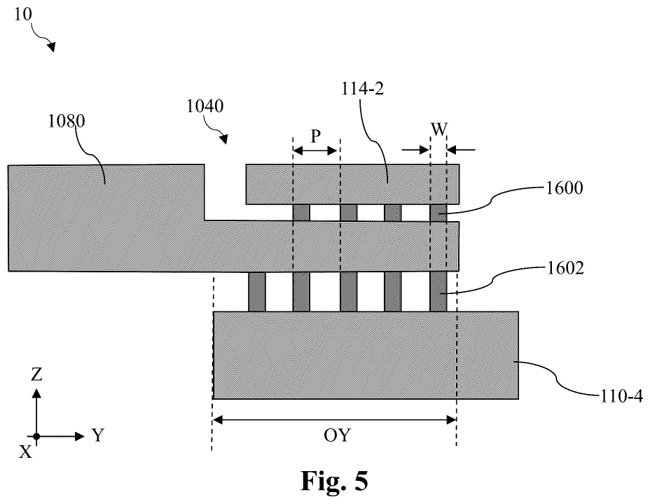

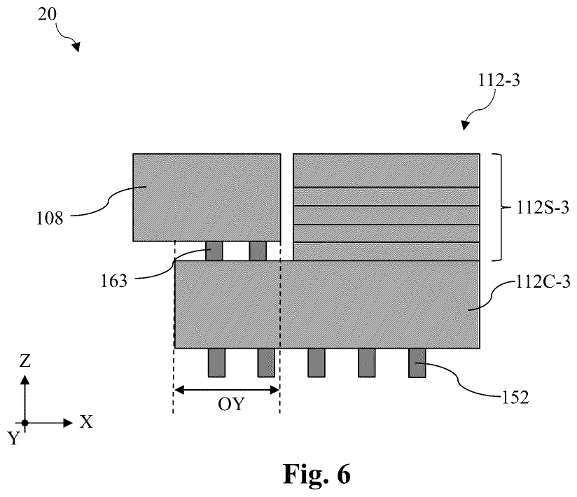

To illustrate the overlapping relationship in more detail, an area 10 in FIG. 2 is enlarged and shown in FIGS. 4 and 5 and an area 20 in FIG. 3 is enlarged and shown in FIG. 6. It should be noted that structures in FIGS. 4 and 5 represent two different configurations that yield the same benefits contemplated in the present disclosure. Reference is first made to FIG. 4. A portion of the system die 108 vertically overlaps with the fourth photonic die 110-4 by the Y-direction overlap (OY). The system die 108 is bonded to the top surface of the fourth photonic die 110-4 by way of the micro bumps 161. The second electronic die 114-2 is bonded to the top surface of the fourth photonic die 110-4 by way of the micro bumps 160. The micro bumps 160 may include a pitch P and a width W along the Y direction. In some instances, the pitch P may be between about 10 μm and about 30 μm and the width W may be between about 5 μm and about 20 μm. Reference is now made to FIG. 5, which illustrates an alternative configuration. Instead of having a photonic die alongside the system die, the alternative configuration includes a carve-out portion 1040 of a system die 1080 and the second electronic die 114-2 is disposed within the carve-out portion 1040. The second electronic die 114-2 is bonded to a top surface of the carve-out portion 1040 of the system die 1080 by way of micro-bumps 1600. A portion of the system die 1080 in FIG. 5 vertically overlaps with the fourth photonic die 110-4 by the Y-direction overlap (OY). In the embodiments represented in FIG. 5, the second electronic die 114-2 vertically overlaps with a portion of the system die 1080 and a portion of the fourth photonic die 110-4. The system die 1080 is bonded to the top surface of the fourth photonic die 110-4 by way of micro bumps 1602. The micro bumps 1602 may include a pitch P and a width W along the Y direction. In some instances, the pitch P may be between about 10 μm and about 30 μm and the width W may be between about 5 μm and about 20 μm.

Reference is now made to FIG. 6. The third memory structure 112-3 includes the third memory stack 112S-3 bonded to the third controller die 112C-3. In order to reduce electrical signal travel distance, the system die 108 vertically overlaps with the third controller die 112C-3. The vertical overlap between the system die 108 and the third controller die 112C-3 along the X direction defines the X-direction overlap (OX). Due to the X-direction overlap (OX), the system die 108 is also bonded to top surfaces of the third controller die 112C-3 by way of micro bumps 163. The third controller die 112C-3 of the third memory structure 112-3 is bonded to the top surface of the interposer 106 by way of micro bumps 152.

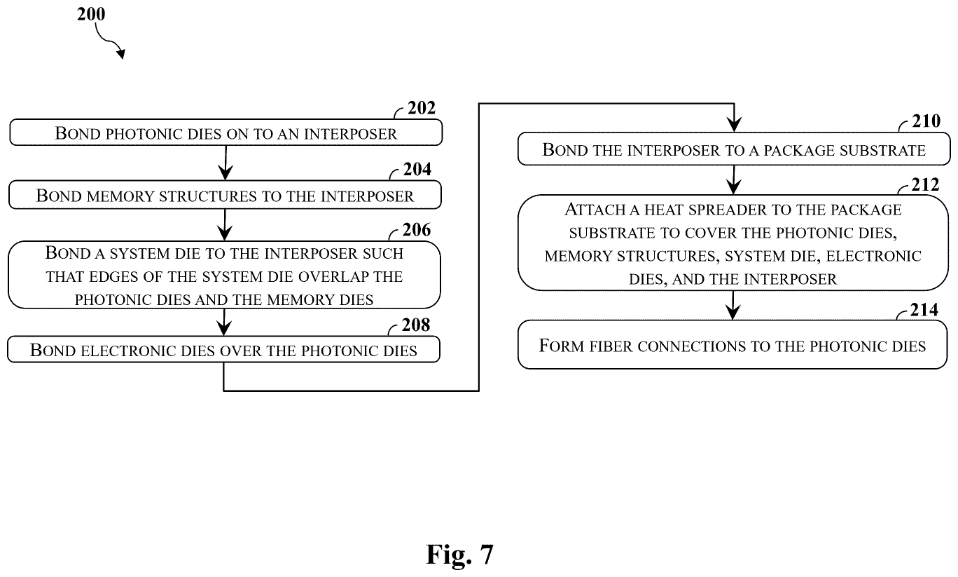

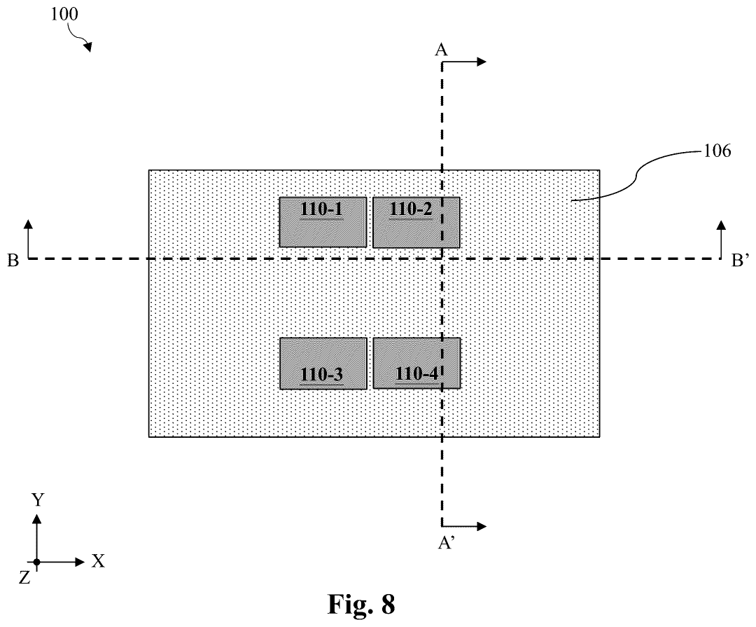

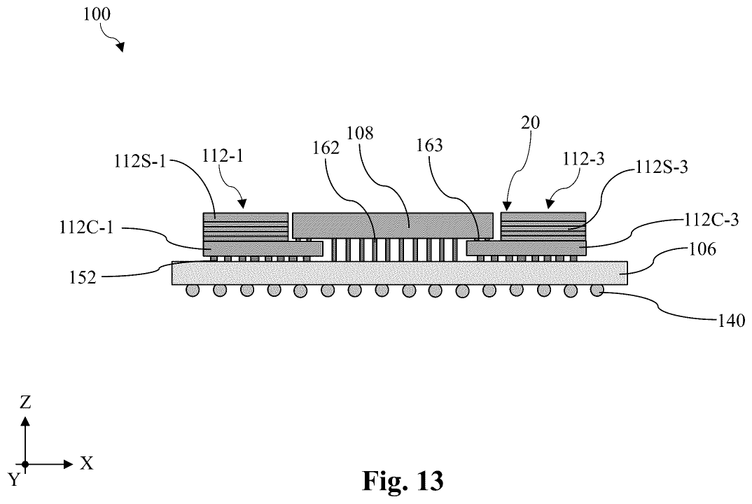

In that regard, FIG. 7 is a flowchart illustrating method 200 of forming the package structure 100 described above. Method 200 is merely an example and is not intended to limit the present disclosure to what is explicitly illustrated in method 200. Additional steps can be provided before, during and after method 200, and some steps described can be replaced, eliminated, or moved around for additional embodiments of the method. Not all steps are described herein in detail for reasons of simplicity. Method 200 is described below in conjunction with FIG. 8-17, which are cross-sectional views or top views of a precursor structure at different stages of fabrication according to various embodiments of method 200. Throughout the present disclosure, unless expressly otherwise described, like reference numerals denote like features.

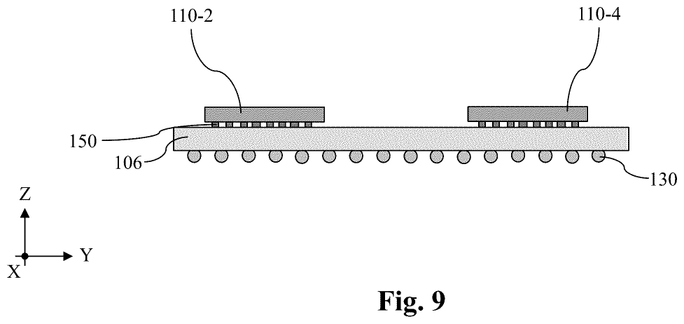

Referring to FIGS. 7, 8 and 9, method 200 includes a block 202 where photonic dies are bonded to an interposer 106. According to the present disclosure, 2 to 4 photonic dies are bonded to the interposer 106. In some embodiments represented in FIGS. 8 and 9, the interposer 106 is bonded to four photonic dies—the first photonic die 110-1, the second photonic die 110-2, the third photonic die 110-3, and the fourth photonic die 110-4. In some embodiments, micro bonding features are formed on contact pads on the photonic dies. In some implementations, each of the micro bonding features includes a metal pillar and a solder feature over the metal pillar. The metal pillar may include copper (Cu), nickel (Ni), or cobalt (Co) and the solder feature includes tin (Sn), silver (Ag), or a combination thereof. At block 202, the photonic dies are placed on a top surface of the interposer 106. The micro bonding features are aligned with contact pads on the interposer 106. An anneal process or a bonding process is then performed to bond the photonic dies to the interposer 106.

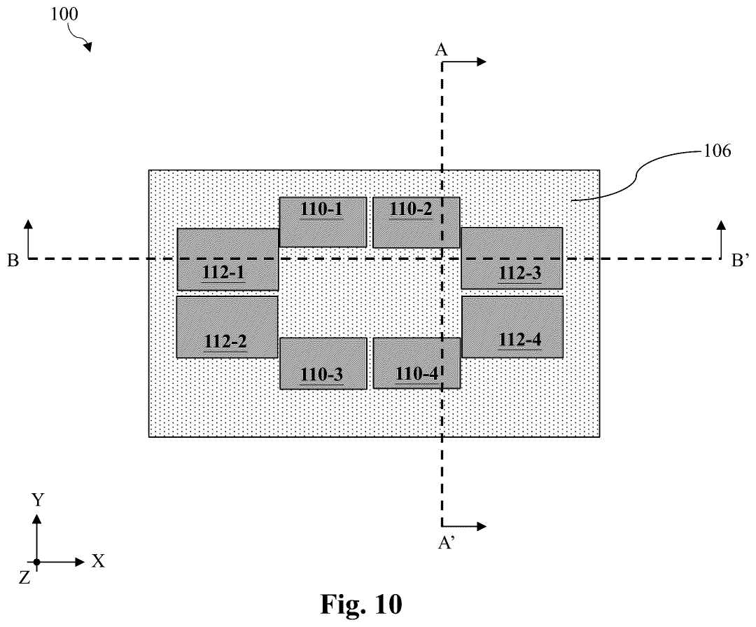

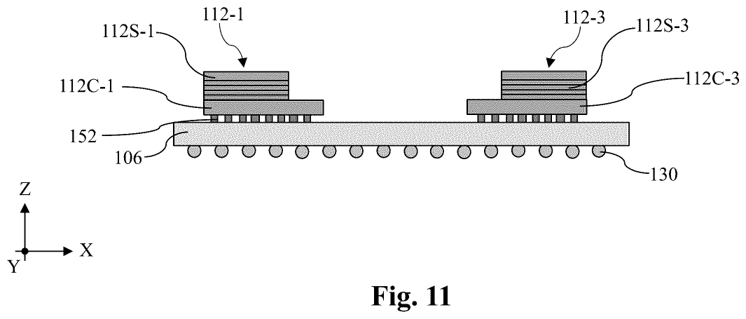

Referring to FIGS. 7, 10 and 11, method 200 includes a block 204 where memory structures are bonded to the interposer 106. According to the present disclosure, 2 to 4 memory structures are bonded to the interposer 106. In some embodiments represented in FIGS. 10 and 11, four memory structures are bonded to the interposer 106. The four memory structures include a first memory structure 112-1, a second memory structure 112-2, a third memory structure 112-3, and a fourth memory structure 112-4. As described above, each of the four memory structures includes a memory stack die bonded to a controller die. In some embodiments, micro bonding features are formed on contact pads on the controller dies. In some implementations, each of the micro bonding features includes a metal pillar and a solder feature over the metal pillar. The metal pillar may include copper (Cu), nickel (Ni), or cobalt (Co) and the solder feature includes tin (Sn), silver (Ag), or a combination thereof. At block 204, the memory structures are placed on the top surface of the interposer 106. The micro bonding features are aligned with contact pads on the interposer 106. An anneal process or a bonding process is then performed to bond the memory structures to the interposer 106.

While photonic dies are depicted as being bonded to the interposer 106 first, the present disclosure fully envisions embodiments where the memory structures are bonded to the interposer 106 first. As will be described further below, a system die 108 is going to be bonded to the interposer 106. Referring to FIG. 10, because it is intended for the system die 108 to partially overlap the photonic dies and the memory structures, the photonic dies and memory structures substantially define a perimeter of a rectangular area. In the depicted embodiments, the photonic dies are divided in two groups that are spaced apart along the Y direction and the memory structures are divided int two groups that are spaced apart along the X direction.

Referring to FIGS. 7, 12 and 13, method 200 includes a block 206 where a system die 108 is bonded to the interposer 106 such that edges of the system die 108 overlap the photonic dies and memory structures. As described above, the system die 108 is to be bonded to the interposer 106 by way of tall micro bumps 162, bonded to the photonic dies by way of the micro bumps 161, and bonded to the controller dies by way of micro bumps 163. In some embodiments, micro bonding features (for micro bumps 161 and 163) and tall micro bonding features (for tall micro bumps 162) are formed on contact pads on the system die 108. In some implementations, each of the micro bonding features includes a metal pillar and a solder feature over the metal pillar. Each of the tall micro bonding features includes a tall metal pillar and a solder feature. A tall metal pillar has a height greater than a height of a metal pillar. The metal pillar and tall metal pillar may include copper (Cu), nickel (Ni), or cobalt (Co) and the solder features include tin (Sn), silver (Ag), or a combination thereof. At block 206, the system die 108 is placed on the top surface of the interposer 106, portions of the photonic dies, and portions of the memory structures. The micro bonding features are aligned with contact pads on the photonic dies and the controller dies. The tall micro bonding features are aligned with contact pads on the interposer. An anneal process or a bonding process is then performed to bond the system die 108 to the photonic dies, memory structures, and the interposer 106.

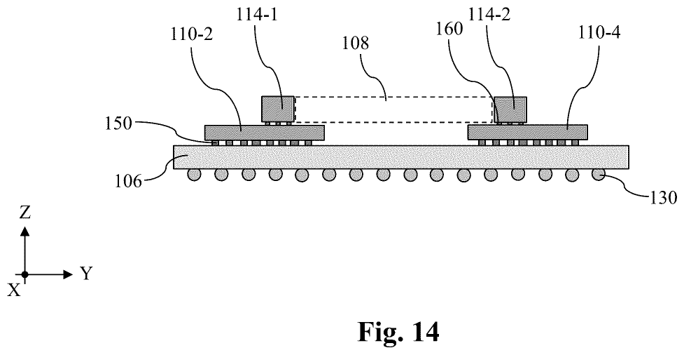

Referring to FIGS. 7 and 14, method 200 includes a block 208 where electronic dies are bonded to the photonic dies. According to the present disclosure, 1 to 2 electronic dies may be bonded to the photonic dies. In some embodiments, each of the electronic dies is configured to bond to two photonic dies. For example, when the package structure includes four photonic dies, two electronic dies are bonded to them as each of the electronic dies bonds to two photonic dies. For another example, when the package structure includes two photonic dies, one electronic die is bonded to the pair of photonic dies. In some embodiments represented in FIG. 14, two electronic dies are bonded to the four photonic dies. The two electronic dies include the first electronic die 114-1 and the second electronic die 114-2. Each of the electronic dies is fabricated to have a configuration to be bonded to the photonic dies while still allowing the system die 108 to overlap with the photonic dies. As described above, electronic dies are to be bonded to the photonic dies by way of the micro bumps 160. In some embodiments, micro bonding features are formed on contact pads on the electronic dies. In some implementations, each of the micro bonding features includes a metal pillar and a solder feature over the metal pillar. The metal pillar may include copper (Cu), nickel (Ni), or cobalt (Co) and the solder feature may include tin (Sn), silver (Ag), or a combination thereof. At block 208, each of the electronic die is placed over top surface of two photonic dies. In the depicted embodiments, the first electronic die 114-1 is placed over the first photonic die 110-1 and the second photonic die 110-2 and the second electronic die 114-2 is placed over the third photonic die 110-3 and the fourth photonic die 110-4. The micro bonding features are aligned with contact pads on the photonic dies. An anneal process or a bonding process is then performed to bond the electronic dies to the photonic dies.

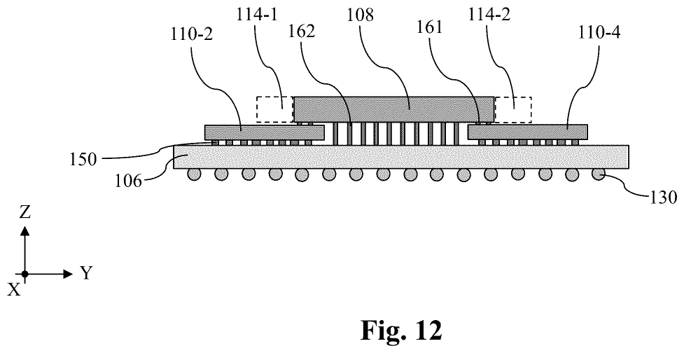

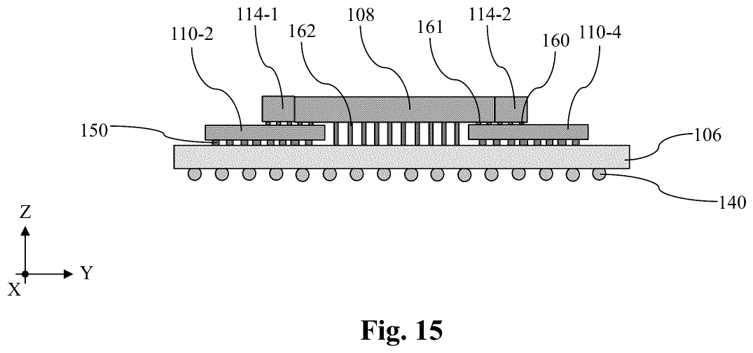

It should be noted that operations at block 208 may be performed before the operations at block 206. Because bonding of the electronic dies and bonding of the system die 108 do not interfere with one another, they may be bonded to the interposer 106/photonic dies in any order. In some instances, operations at block 206 may be performed before operations at block 208. In some instances, operations at block 208 may be performed before operations at block 206. This is why the first photonic die 114-1 and the second photonic die 114-2 are shown in dotted lines in FIG. 12 and why the system die 108 is shown in dotted lines in FIG. 14. Upon completion of operations at block 206 and 208, the photonic dies, memory structures, the system die 108, and the electronic dies are all bonded to the interposer 106, as illustrated in FIG. 15.

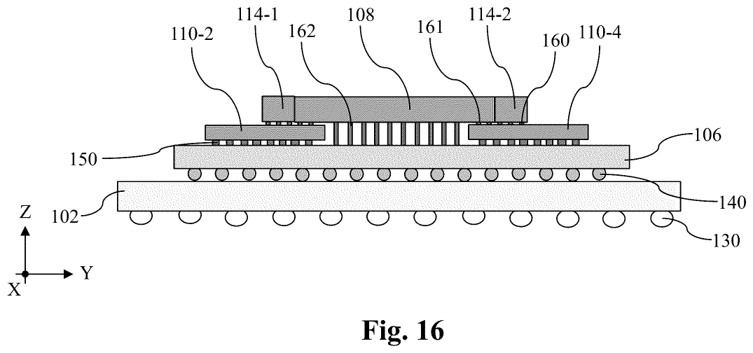

Referring to FIGS. 7 and 16, method 200 includes a block 210 where the interposer 106 is bonded to the package substrate 102. In some embodiments, controlled collapse chip connection (C4) bumps 140 are formed on contact pads on a back surface of the interposer 106. The contact pads on the interposer may include under-bump-metallurgy (UBM) bumps. The C4 bumps 140 are greater in dimensions then the micro bumps described above. The C4 bumps 140 may include lead, tin, silver, or alloy thereof. After formation of the C4 bumps 140, the interposer 106 is placed on the package substrate 102 such that the C4 bumps 140 are aligned with contact pads on the package substrate 102. An anneal process or a bonding process is then performed to bond the interposer 106 to the package substrate 102.

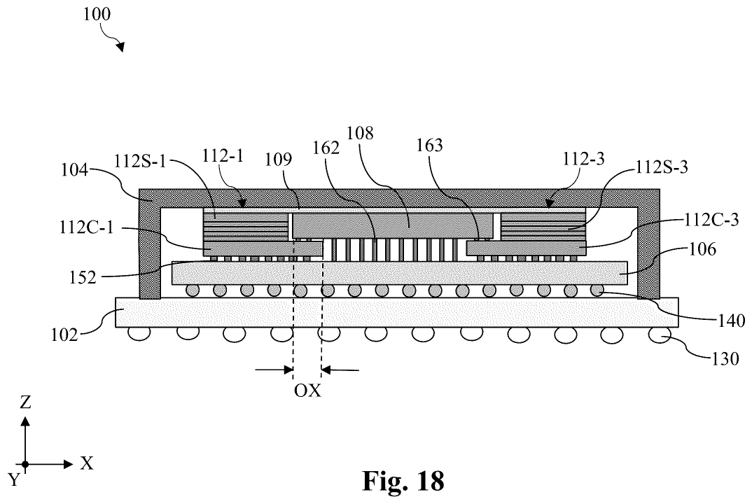

Referring to FIGS. 7, 17 and 18, method 200 includes a block 212 wherein a heat spreader 104 is attached to the package substrate 102 to cover the photonic dies, memory structures, system dies, electronic dies, and the interposer. As described above, the heat spreader 104 is formed of a metal or a metal alloy, such as aluminum (Al), copper (Cu), iron (Fe), stainless steel, nickel (Ni), cobalt (Co), or an alloy thereof. Example alloys may include an aluminum-copper alloy, an iron-nickel alloy, or an iron-nickel-cobalt alloy. Because the heat spreader 104 includes metal, it may also be referred to as a metal lid. At block 212, the thermally conductive layer 109 is form over top surfaces of the electronic dies, the system die, and controller dies and an adhesive is dispensed in a landing area on the package substrate 102. The thermally conductive layer 109 may include TIM materials, which may include a gallium alloy, zinc oxide (ZnO), or aluminum nitride (AlN). When the TIM materials are liquid, they can be dispensed over top surfaces of the dies to form the thermally conductive layer 109. The adhesive may include a die attach film (DAF), silicone, polyimide (PI), or epoxy. The heat spreader 104 is then placed over the package substrate 102 such that its bottom surface engages the thermally conductive layer 109 and a lower edge of sidewalls of the heat spreader 104 engages the adhesive. A curing process, such as an anneal process, is then performed to cure the thermally conductive layer 109 and the adhesive to bond the heat spreader 104 to package substrate 102.

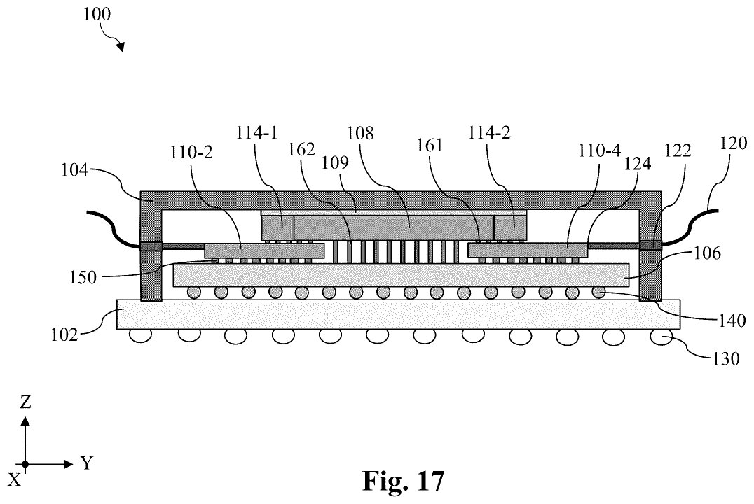

Referring to FIGS. 7 and 17, method 200 includes a block 214 where fiber connections are formed to the photonic dies. In some embodiments, the fiber connections are formed before the attachment of the heat spreader 104 and the heat spreader 104 includes slots or openings to accommodate such fiber connections. In some embodiments, the fiber connections are formed after the attachment of the heat spreader 104 through slots or openings on the heat spreader 104. In general, the fiber connections include three components—a fiber array 120, a fiber connector 122 that physically engages a sidewall of the heat spreader 104, and a coupler 124 configured to couple to the fiber array 120. The coupler 124 may include an edge coupler or a grating coupler. When the coupler 124 is an edge coupler, the coupler 124 is disposed along a sidewall of the photonic die, such as the second photonic die 110-2 or the fourth photonic die 110-4. When the coupler 124 is a grating coupler, the coupler 124 is disposed along a top surface of the photonic die, such as the second photonic die 110-2 or the fourth photonic die 110-4.

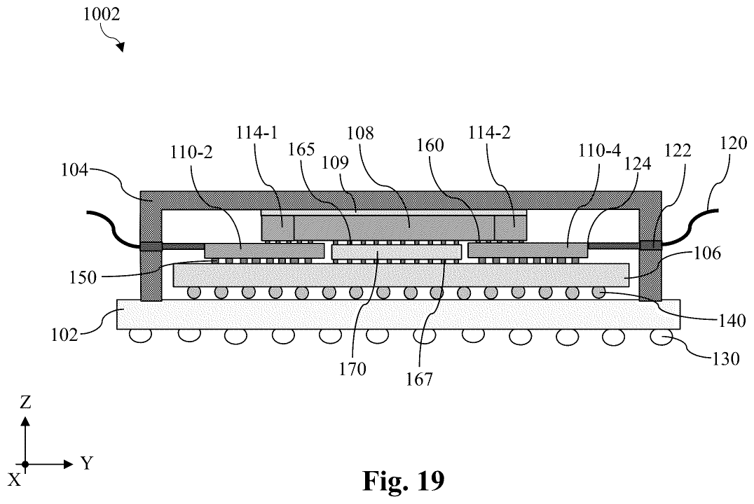

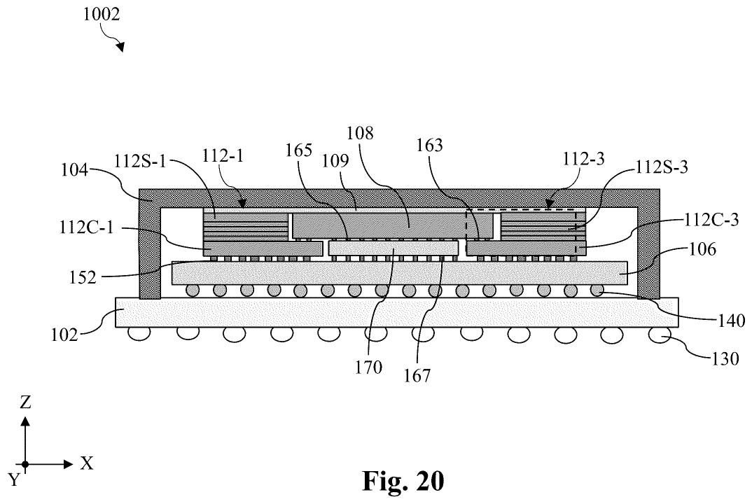

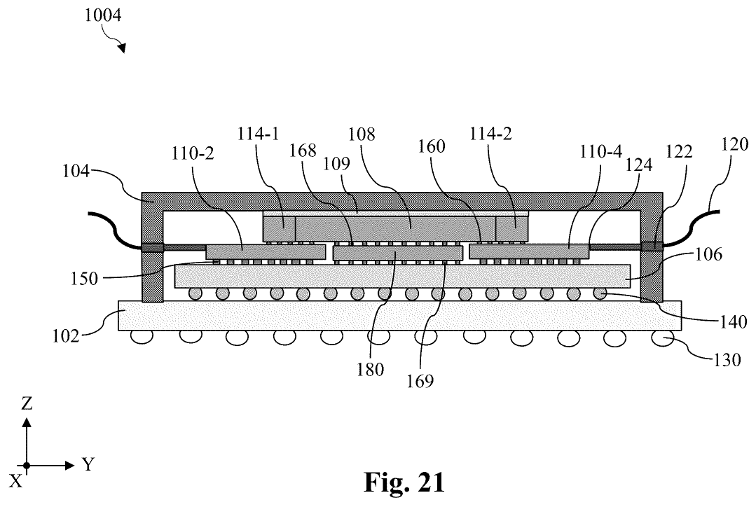

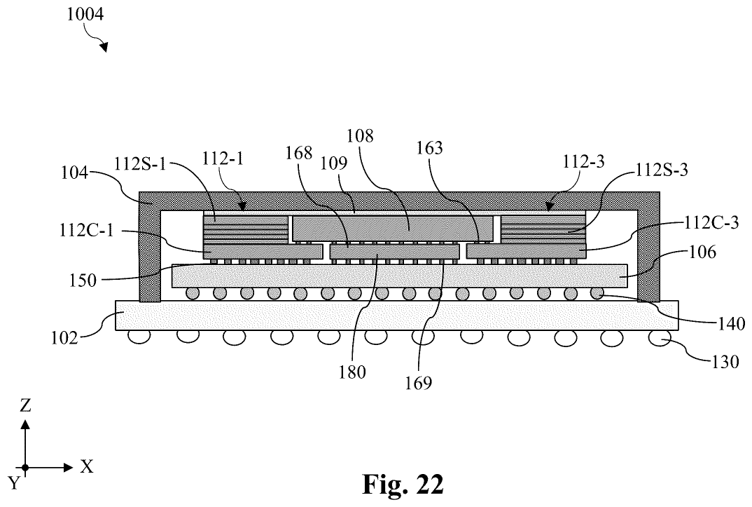

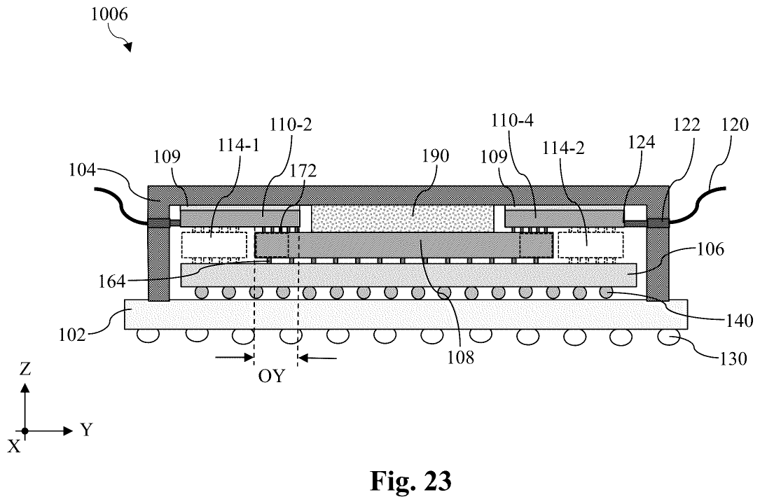

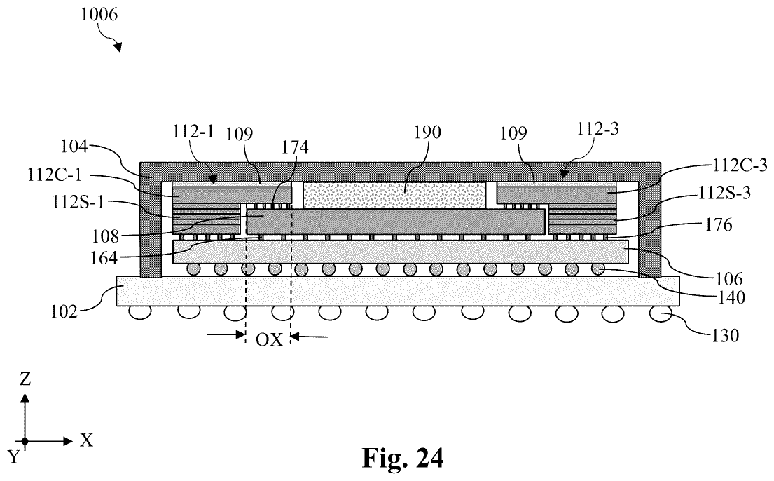

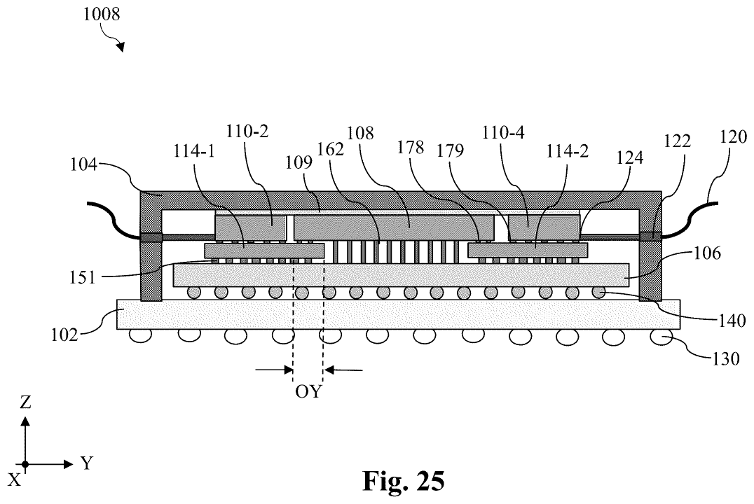

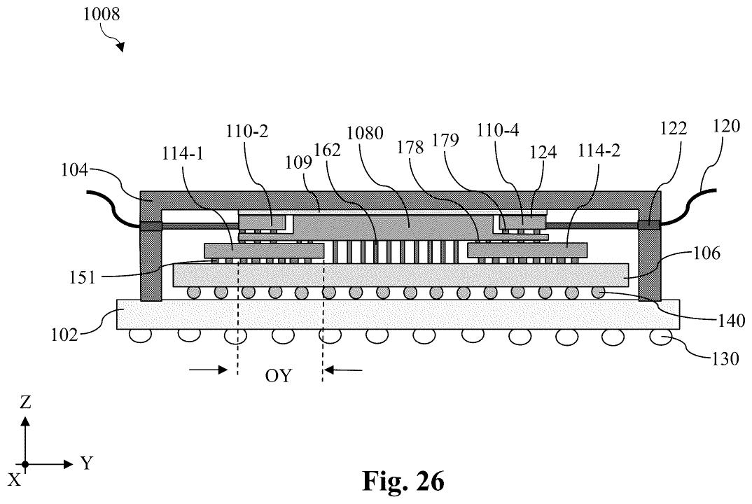

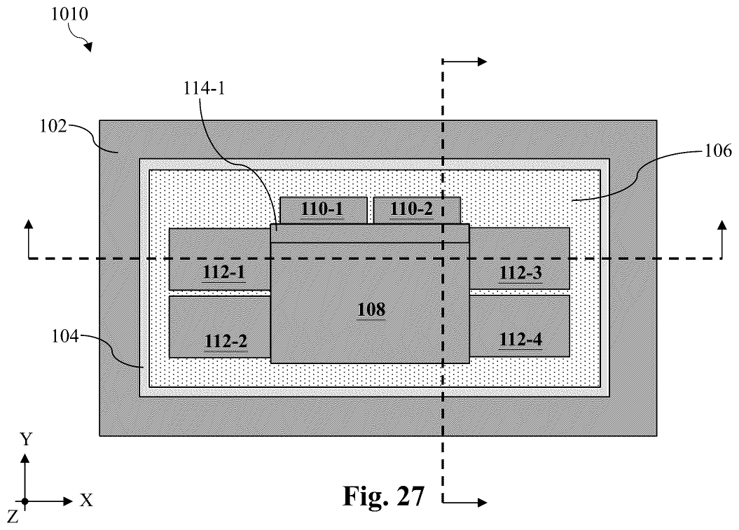

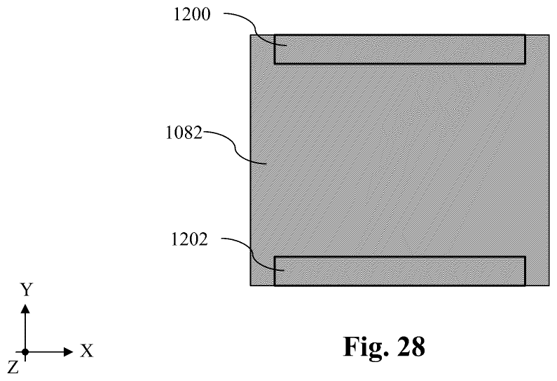

FIGS. 19-27 illustrate alternative embodiments. FIGS. 19 and 20 illustrate an alternative embodiment where a decoupling capacitor die 170 is disposed vertically between the system die 108 and the interposer 106. FIGS. 21 and 22 illustrate an alternative embodiment where an input/output die 180 is disposed vertically between the system die 108 and the interposer 106. FIGS. 23 and 24 illustrate an alternative embodiment where photonic dies and controller dies are bonded to a top surface of the system die 108. FIGS. 25 and 26 illustrate an alternative embodiment where photonic dies and electronic dies switch positions. FIG. 27 illustrates an alternative embodiment where the package structure 100 includes two photonic dies. FIG. 28 illustrates an alternative embodiment where electronic dies are integrated in the system die 108.

FIGS. 19 and 20 illustrate cross-sectional views of a package structure 1002. The package structure includes a decoupling capacitor die 170 bonded to the system die 108 and the interposer 106 by way of micro bumps 165 and micro bumps 167. The decoupling capacitor die 170 includes decoupling capacitors that are designed to isolate the circuit in the system die 108 from noise and anomalies from other devices or dies that are coupled to the same power supply. As shown in FIGS. 19 and 20, the decoupling capacitor die 170 is disposed vertically between the system die 108 and the interposer 106. Along the Y direction, the decoupling capacitor die 170 is disposed between the second photonic die 110-2 and the fourth photonic die 110-4, as shown in FIG. 19. Along the X direction, the decoupling capacitor die 170 is disposed between the first controller die 112C-1 and the third controller die 112C-3, as shown in FIG. 20.

FIGS. 21 and 22 illustrate cross-sectional views of a package structure 1004. The package structure 1004 includes an input/output (I/O) die 180 bonded to the system die 108 and the interposer 106 by way of micro bumps 168 and micro bumps 169. The I/O die 180 may act as an interface between the system die 108 and peripheral dies. In some embodiments, the I/O die 180 may redistribute signal from the system die 108 to couple to the interposer 106. As shown in FIGS. 21 and 22, the I/O die 180 is disposed vertically between the system die 108 and the interposer 106. Along the Y direction, the I/O die 180 is disposed between the second photonic die 110-2 and the fourth photonic die 110-4, as shown in FIG. 21. Along the X direction, the I/O die 180 is disposed between the first controller die 112C-1 and the third controller die 112C-3, as shown in FIG. 22.

FIGS. 23 and 24 illustrate cross-sectional views of a package structure 1006. In embodiments representatively shown in FIGS. 2, 3, 17, and 18, the photonic die and the controller dies are bonded to the interposer 106 and the system die 108 is bonded such that portions of the photonic dies and the controller dies are disposed between the system die 108 and the interposer 106. In the package structure 1006, the photonic dies and the controller dies are bonded to the top surface of the system die 108. The system die 108 is bonded to the interposer 106 by way of micro bumps 164. The photonic dies, such as the second photonic die 110-2 and the fourth photonic die 110-4, are bonded to the top surface of the system die 108 by way of micro bumps 172 and overhang the interposer 106. A thermal spreading layer 190 is disposed directly on the system die 108. The thermal spreading layer 190 may include thermal interface material (TIM), a metal, or a metal ally. In some instances, the thermal spreading layer 190 includes a gallium alloy, zinc oxide (ZnO), aluminum nitride (AlN), aluminum (Al), copper (Cu), iron (Fe), stainless steel, nickel (Ni), cobalt (Co), an aluminum-copper alloy, an iron-nickel alloy, or an iron-nickel-cobalt alloy As shown in FIG. 23, the thermal spreading layer 190 is disposed between two groups of the photonic dies along the Y direction. From over the system die 108, each of the photonic dies vertically overlaps the system die 108 by a Y-direction overlap (OY). In some instances, the Y-direction overlap (OY) is between about 500 μm and about 1000 μm. As shown in FIG. 23, a fiber array 120 is coupled to a coupler 124 on each of the photonic dies via a fiber connector 122 that extends through a sidewall of the heat spreader 104. In some embodiments, the coupler 124 may be an edge coupler or a grating coupler. When the coupler 124 is an edge coupler, the coupler 124 is disposed along a sidewall of the photonic die, such as the second photonic die 110-2 or the fourth photonic die 110-4. When the coupler 124 is a grating coupler, the coupler 124 is disposed along a top surface of the photonic die, such as the second photonic die 110-2 or the fourth photonic die 110-4. Because top surfaces of the photonic dies and the thermal spreading layer 190 engage a bottom surface of the heat spreader 104, the coupler 124 may be disposed at a lower edge of the photonic dies closer to the interposer 106. The bottom surface of the heat spreader 104 interfaces top surfaces of the controller dies and photonic dies by way of the thermally conductive layer 109.

As shown in dotted lines in FIG. 23, the electronic dies, such as the first electronic die 114-1 and the second electronic die 114-2 may be bonded directly between the photonic dies (such as the second photonic die 110-2 and the fourth photonic die 110-4) by way of micro bumps. Alternatively, functions of the first electronic die 114-1 and the second electronic die 114-2 may be performed by allocated electronic die area in the system die 108. As will be described further below in FIG. 28, such a system die 108 may be referred to as an integrated system die.

Referring to FIG. 24, the memory structures are bonded both to the system die 108 and the interposer 106. The controller dies, such as the first controller die 112-1 and the third controller die 112-3, are coupled to the top surface of the system die 108 by way of the micro bumps 174. The memory stack dies, such as the first memory stack 112S-1 and the third memory 112S-3, are bonded to the top surface of interposer 106 by way of micro bumps 176. Along the X direction, the thermal spreading layer 190 is disposed between the first controller die 112C-1 and the third controller die 112C-3. The system die 108 is disposed between the first memory stack 112S-1 and the third memory stack 112S-3 along the X direction. From over the system die 108, each of the controller dies vertically overlaps the system die 108 by an X-direction overlap (OX). In some instances, the X-direction overlap (OX) is between about 500 μm and about 1000 μm.

FIGS. 25 and 26 illustrate cross-sectional views of a package structure 1008. As compared to the embodiments representatively shown in FIGS. 2, 3, 17, and 18, the photonic dies and the electronic dies in the package structure 1008 switch places. Referring to FIG. 25, the first electronic die 114-1 and the second electronic die 114-2 are directly bonded to the interposer 106 by way of micro bumps 151 and photonic dies are bonded to a top surface of the electronic dies by way of micro bumps 160. The photonic dies are now alongside the system die 108. Along the Y direction, the system die 108 is disposed between the second photonic die 110-2 and the fourth photonic die 110-4. The system die 108 vertical overlaps each of the electronic dies by a Y-direction overlap (OY). In some instances, the Y-direction overlap (OY) is between about 500 μm and about 1000 μm. As shown in FIG. 25, a fiber array 120 is coupled to a coupler 124 on a lower edge of each of the photonic dies via a fiber connector 122 that extends through a sidewall of the heat spreader 104. In some embodiments, the coupler 124 may be an edge coupler or a grating coupler. When the coupler 124 is an edge coupler, the coupler 124 is disposed along a sidewall of the photonic die, such as the second photonic die 110-2 or the fourth photonic die 110-4. When the coupler 124 is a grating coupler, the coupler 124 is disposed along a top surface of the photonic die, such as the second photonic die 110-2 or the fourth photonic die 110-4.

In some embodiments represented in FIG. 26, the first electronic die 114-1 and the second electronic die 114-2 are directly bonded to the interposer 106 by way of micro bumps 151. The system die 1080 includes carve-out portions. The photonic dies are disposed within the carve-out portions and bonded to the system die 108. The photonic dies are disposed alongside the system die 108. Along the Y direction, the system die 108 is disposed between the second photonic die 110-2 and the fourth photonic die 110-4. The system die 108 vertical overlaps each of the electronic dies by a Y-direction overlap (OY). In some instances, the Y-direction overlap (OY) is between about 500 μm and about 1000 μm. As shown in FIG. 26, a fiber array 120 is coupled to a coupler 124 on each of the photonic dies via a fiber connector 122 that extends through a sidewall of the heat spreader 104. In some embodiments, the coupler 124 may be an edge coupler or a grating coupler. When the coupler 124 is an edge coupler, the coupler 124 is disposed along a sidewall of the photonic die, such as the second photonic die 110-2 or the fourth photonic die 110-4. When the coupler 124 is a grating coupler, the coupler 124 is disposed along a top surface of the photonic die, such as the second photonic die 110-2 or the fourth photonic die 110-4.

FIG. 27 includes a package structure 1010. Compared to embodiments representatively shown in FIGS. 2, 3, 17, and 18, the package structure 1010 includes two photonic dies and one electronic die over the two photonic dies. As illustrated in FIG. 27, the first electronic die 114-1 is disposed along an edge of the system die 108 and bonded to top surfaces of the first photonic die 110-1 and the second photonic die 110-2. In some embodiments represented in FIG. 27, the package structure 1010 includes the first memory structure 112-1, the second memory structure 112-2, the third memory structure 112-3, and the fourth memory structure 112-4. Like the embodiments representatively shown in FIGS. 2, 3, 17, and 18, the system die 108 vertically overlaps with the first photonic die 110-1 and the second photonic die 110-2 by the Y-direction overlap (OY). The system die 108 vertically overlaps with controller dies of the first memory structure 112-1, the second memory structure 112-2, the third memory structure 112-3, and the fourth memory structure 112-4 by the X-direction overlap (OX). As shown in FIG. 27, the interposer 106, the first memory structure 112-1, the second memory structure 112-2, the third memory structure 112-3, the fourth memory structure 112-4, the first photonic die 110-1, the second photonic die 110-2, and the system die 108 are covered by the heat spreader 104 that is attached to the package substrate 102.

FIG. 28 includes an integrated system die 1082 that includes blocks that perform electronic die functions. In some embodiments represented in FIG. 28, the integrated system die 1082 includes a first block 1200 and a second block 1202 that integrate circuitry to perform electronic die functions. The integrated system die 1082 may perform functions of and replace the system die 108, the first electronic die 114-1 and the second electronic die 114-2 shown in FIGS. 1-3, 17-18, 19-20, and 21-22. For avoidance of doubts, the integrated system die 1082 in FIG. 28 is a single die. In some instances, each of the first block 1200 and the second block 1202 may be obtained by repurposing two serializer/deserializer areas in the integrated system die 1082.

The present disclosure provides many embodiments. In one aspect, the present disclosure provides a package structure. The package structure includes a package substrate, an interposer disposed over the package substrate, a photonic die disposed over the interposer, a memory structure disposed over the interposer and including a controller die, a system die disposed over the interposer and partially overlapping with the photonic die and the controller die, and a lid covering the system die, the memory structure, and photonic die. The system die includes micro bumps extending from a bottom surface of the system die to a top surface of the controller die.

In some embodiments, the package structure further includes an electronic die disposed on the photonic die and extending along an edge of the system die. In some embodiments, the system die further includes tall micro bumps extending from the bottom surface of the system die to a top surface of the interposer. In some implementations, the package structure further includes a decoupling capacitor disposed between the interposer and the system die. In some embodiments, the package structure further includes an input/output die disposed between the interposer and the system die. In some embodiments, the photonic die includes an edge coupler, and the edge coupler is coupled to a fiber array. In some instances, a portion of the system die extends between a bottom surface of the electronic due and a top surface of the photonic die. In some embodiments, the partially overlapping between the photonic die and the controller die defines an overlapping width between about 500 μm and about 1000 μm.

In another aspect, the present disclosure provides a package structure. The package structure includes a package substrate, an interposer disposed over the package substrate, a first photonic die and a second photonic die disposed over the interposer and spaced apart from one another along a first direction, a first memory structure and a second memory structure disposed over the interposer and spaced apart from one another along a second direction perpendicular to the first direction, the first memory structure including a first controller die and the second memory structure including a second controller die, a system die disposed over the interposer and partially overlapping with the first controller die, the second controller die, the first photonic die, and the second photonic die, and a lid covering the system die, the first memory structure, the second memory structure, the first photonic die, and the second photonic die. The system die includes micro bumps extending from a bottom surface of the system die to top surfaces of first controller die and the second controller die.

In some embodiments, the first photonic die includes a first edge coupler, and the second photonic die includes a second edge coupler. In some embodiments, the package structure further includes tall micro bumps extending from the bottom surface of the system die to a top surface of the interposer. In some embodiments, the package structure further includes a die disposed vertically between the interposer and the system die and between the first photonic die and the second photonic die along the first direction. In some embodiments, the die includes a decoupling capacitor die or an input/output die. In some embodiments, the system die is coupled to the die by way of first micro bumps, and the die is coupled to the interposer by way of second micro bumps. In some implementations, the package structure further includes a first electronic die disposed over the first photonic die and a second electronic die disposed over the second photonic die. The system die is disposed between the first electronic die and the second electronic die along the first direction.

In still another aspect, the present disclosure provides a package structure. The package structure includes a package substrate, an interposer disposed over the package substrate, a system die disposed over the interposer, a first photonic die and a second photonic die disposed over and overhanging the system die, a first memory structure and a second memory structure disposed over the interposer, the first memory structure including a first controller die and a first memory stack bonded to the first controller die and the second memory structure including a second controller die and a second memory stack bonded to the second controller die, and a lid covering the system die, the first memory structure, the second memory structure, the first photonic die, and the second photonic die. A portion of the first controller die and a portion of the second controller die span over a top surface of the system die.

In some embodiments, the first photonic die and the second photonic die are spaced apart from one another along a first direction. The first memory structure and the second memory structure are spaced apart from one another along a second direction perpendicular to the first direction. In some embodiments, the package structure further includes a thermal spreading layer disposed between the top surface of the system die and a bottom surface of the lid. In some embodiments, the thermal spreading layer is disposed between the first controller die and the second controller die along the second direction. In some implementations, the system die is disposed between the first memory stack and the second memory stack along the second direction.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
an interposer disposed over the package substrate;
a photonic die disposed over the interposer;
a memory structure disposed over the interposer and comprising a controller die;
a system die disposed over the interposer and partially overlapping with the photonic die and the controller die; and
a lid covering the system die, the memory structure, and photonic die,
wherein the system die includes micro bumps extending from a bottom surface of the system die to a top surface of the controller die.

2. The package structure of claim 1, further comprising:
an electronic die disposed on the photonic die and extending along an edge of the system die.

3. The package structure of claim 1, wherein the system die further includes tall micro bumps extending from the bottom surface of the system die to a top surface of the interposer.

4. The package structure of claim 1, further comprising:
a decoupling capacitor disposed between the interposer and the system die.

5. The package structure of claim 1, further comprising:
an input/output die disposed between the interposer and the system die.

6. The package structure of claim 1,
wherein the photonic die comprises an edge coupler, and
wherein the edge coupler is coupled to a fiber array.

7. The package structure of claim 2,
wherein a portion of the system die extends between a bottom surface of the electronic due and a top surface of the photonic die.

8. The package structure of claim 1, wherein the partially overlapping between the photonic die and the controller die defines an overlapping width between about 500 μm and about 1000 μm.

9. A package structure, comprising:
a package substrate;
an interposer disposed over the package substrate;
a first photonic die and a second photonic die disposed over the interposer and spaced apart from one another along a first direction;
a first memory structure and a second memory structure disposed over the interposer and spaced apart from one another along a second direction perpendicular to the first direction, the first memory structure comprising a first controller die and the second memory structure comprising a second controller die;
a system die disposed over the interposer and partially overlapping with the first controller die, the second controller die, the first photonic die, and the second photonic die; and
a lid covering the system die, the first memory structure, the second memory structure, the first photonic die, and the second photonic die,
wherein the system die includes micro bumps extending from a bottom surface of the system die to top surfaces of first controller die and the second controller die.

10. The package structure of claim 9,
wherein the first photonic die comprises a first edge coupler, and
wherein the second photonic die comprises a second edge coupler.

11. The package structure of claim 9, further comprising:
tall micro bumps extending from the bottom surface of the system die to a top surface of the interposer.

12. The package structure of claim 9, further comprising:
a die disposed vertically between the interposer and the system die and between the first photonic die and the second photonic die along the first direction.

13. The package structure of claim 12, wherein the die comprises a decoupling capacitor die or an input/output die.

14. The package structure of claim 12,
wherein the system die is coupled to the die by way of first micro bumps, and
wherein the die is coupled to the interposer by way of second micro bumps.

15. The package structure of claim 9, further comprising:
a first electronic die disposed over the first photonic die; and
a second electronic die disposed over the second photonic die,
wherein the system die is disposed between the first electronic die and the second electronic die along the first direction.

16. A package structure, comprising:
a package substrate;
an interposer disposed over the package substrate;
a system die disposed over the interposer;
a first photonic die and a second photonic die disposed over and overhanging the system die;
a first memory structure and a second memory structure disposed over the interposer, the first memory structure comprising a first controller die and a first memory stack bonded to the first controller die and the second memory structure comprising a second controller die and a second memory stack bonded to the second controller die; and
a lid covering the system die, the first memory structure, the second memory structure, the first photonic die, and the second photonic die,
wherein a portion of the first controller die and a portion of the second controller die span over a top surface of the system die.

17. The package structure of claim 16,
wherein the first photonic die and the second photonic die are spaced apart from one another along a first direction,
wherein the first memory structure and the second memory structure are spaced apart from one another along a second direction perpendicular to the first direction.

18. The package structure of claim 17, further comprising:
a thermal spreading layer disposed between the top surface of the system die and a bottom surface of the lid.

19. The package structure of claim 18, wherein the thermal spreading layer is disposed between the first controller die and the second controller die along the second direction.

20. The package structure of claim 17, wherein the system die is disposed between the first memory stack and the second memory stack along the second direction.
